(19) United States
(12) Patent Application Publication
(10) Pub. No.: US 2018/0209027 A1
(43) Pub. Date: Jul. 26, 2018

(54) MASK FOR SPUTTERING FILM FORMATION AND SPUTTERING DEVICE

(71) Applicant: BOE TECHNOLOGY GROUP CO., LTD., Beijing (CN)

(72) Inventors: Zhongpeng Tian, Beijing (CN); Yimin Chen, Beijing (CN); Xuewei Gao, Beijing (CN); Jie Wu, Beijing (CN); Lei Xiao, Beijing (CN)

(21) Appl. No.: 15/710,067

(22) Filed: Sep. 20, 2017

(30) Foreign Application Priority Data
Jan. 23, 2017 (CN) 201710059099.6

(51) Int. Cl. C23C 14/04; C23C 14/35; C23C 14/50

(52) U.S. Cl. CPC C23C 14/04; C23C 14/50; C23C 14/35

(57) ABSTRACT

A mask and a sputtering device are provided for sputtering film formation. The mask includes a mask body which further includes a sputtering face with a plurality of protrusions positioned thereupon.

### CROSS-REFERENCE TO RELATED APPLICATIONS

This application claims priority to Chinese Patent Application No. 201710059099.6, filed on Jan. 23, 2017, the disclosure of which is incorporated herein by reference in its entirety.

### TECHNICAL FIELD

The present disclosure relates to the field of sputtering film formation technology, and in particular to a mask for sputtering film formation and sputtering device.

### BACKGROUND

Magnetron sputtering methods have been widely used due to features such as good film-forming speed, good uniformity in film-forming, and good adhesion between the substrate and the film formed thereupon. The basic principle of magnetron sputtering is: generating high density charges in a vacuum via an electromagnetic field, hitting the target with the charges via attraction by the electric field of the target, and sputtering a volume of target atoms onto the substrate to form the film.

However, when the target is hit with magnetron sputtering, a film may also be formed on the mask while the film is formed onto the substrate. When the target includes a non-metal material, and as the non-metal film formed on the mask increases in thickness, powders are generated because non-metal film cannot be packed densely, such that powders may drop onto the substrate that is being coated with a film. The invasion of the powder affects the normal growth of the film being formed on the substrate and hence the electric properties of the formed film, and therefore the quality of the formed film may thus be negatively affected.

To solve the aforementioned issues, related technologies employ the method of opening the cavity and removing the powder after a period of 3 to 5 days of continuous film forming. This method however severely affects the production efficiencies, and because it often takes a long time to recreate the vacuum as needed every time after the cavity is opened, this method unavoidably affects the quality of the film as formed.

### SUMMARY

In a first aspect, a mask is provided for sputtering film formation. The mask includes a mask body which further includes a sputtering face with a plurality of protrusions positioned thereupon.

Optionally, the mask body includes an outer periphery being a rectangle in shape, the protrusions are strip-like protrusions positioned side-by-side along a longitudinal direction of a side of the mask body, and a longitudinal direction of the protrusions intersects the longitudinal direction of the side of the mask body.

Optionally, the strip-like protrusions are straight strip-like protrusions each including two side walls extending along the longitudinal direction of the strip-like protrusions, and the two side walls include a first side wall at an acute angle relative to the mask body.

Optionally, the first side walls of the strip-like protrusions are at an identical acute angle relative to the mask body.

Optionally, the acute angle of the first side wall relative to the mask body is in a range of 45 degrees to 60 degrees.

Optionally, the two side walls further include a second side wall arranged obliquely relative to the mask body.

Optionally, the first and second side walls are parallel to each other.

Optionally, the first side wall is of a width of 4 millimeters to 5 millimeters.

Optionally, two adjacent protrusions include bottom portions spaced apart from each other by a distance between 1 millimeter and 4 millimeters, and the bottom portions are end portions contacting the mask body.

Optionally, each of the protrusions has a curved top protruding away from the mask body.

Optionally, the protrusions are uniformly positioned on the mask body.

Optionally, the protrusions are integrally formed with the mask body.

Optionally, the protrusions are granular in shape.

Optionally, the mask further includes a retaining wall positioned at a periphery of a face of the mask body upon which the protrusions are positioned.

In a second aspect, a sputtering device is provided to include: a substrate platform, a target holder to position a target, and a mask positioned between the substrate platform and the target holder. The mask includes a mask body which further includes a sputtering face with a plurality of protrusions positioned thereupon.

### BRIEF DESCRIPTION OF THE DRAWINGS

To further clarify the technical solutions of embodiment(s) of the present disclosure or related technologies, below is a brief introduction of the drawings mentioned in the described embodiment(s) or related technologies. Evidently, the drawings are merely related to some of the embodiment(s) of the present disclosure. Technical personnel skilled in the art may be able to derive other drawing(s) from the drawings described herein without creative effort.

FIG. 1(a) illustratively depicts a mask according to some embodiments of the present disclosure;

FIG. 1(b) illustratively depicts a mask according to some embodiments of the present disclosure;

FIG. 1(c) illustratively depicts a mask according to some embodiments of the present disclosure;

FIG. 2(a) illustratively depicts a mask according to some embodiments of the present disclosure;

FIG. 2(b) is a cross-sectional view of FIG. 2(a) taken along line AA;

FIG. 2(c) illustratively depicts a mask according to some embodiments of the present disclosure;

FIG. 2(d) illustratively depicts a mask according to some embodiments of the present disclosure;

FIG. 3 illustratively depicts a mask according to some embodiments of the present disclosure;

FIG. 4 illustratively depicts a mask according to some embodiments of the present disclosure;

FIG. 5 illustratively depicts a sputtering device according to some embodiments of the present disclosure; and

FIG. 6 illustratively depicts a sputtering device according to some embodiments of the present disclosure.

The reference numerals are:
01—substrate platform; 02—target holder;
03—mask; 10—mask body;
20—protrusions; 201—first side wall;
202—second side wall; 30—retaining wall;
40—substrate to-be-coated; 50—target.

### DETAILED DESCRIPTION

Technical solutions of the embodiments of the present disclosure are described herein below with further clarity and completeness in conjunction with the drawings mentioned in the embodiments of the present disclosure. Certainly, the described embodiments are merely part of and not all of the embodiments of the present disclosure. Based on the embodiments of the present disclosure, all other embodiments obtained by the technical personnel skilled in the art are also within the scope of the present disclosure.

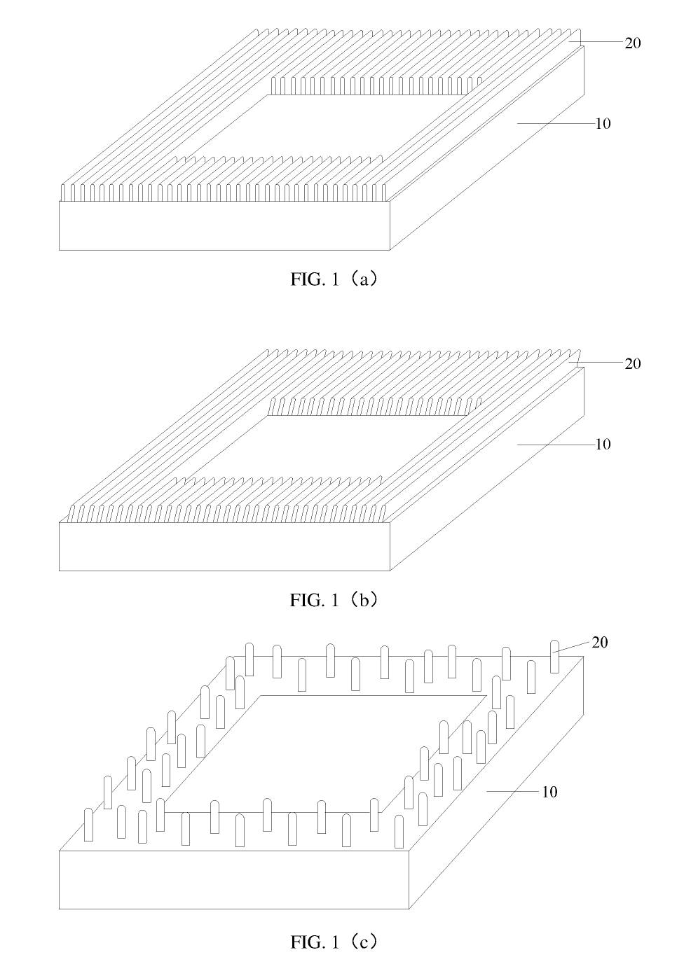

Some embodiments of the present disclosure provide a mask for sputtering film formation. As shown in FIG. 1 through FIG. 4, the mask includes a mask body 10 with a hollow portion, and the mask body 10 includes a sputtering face with protrusions 20 positioned thereupon.

The protrusions 20 are not limited in shape, and may be of a strip-like shape as illustratively depicted in FIG. 1(a) and FIG. 1(b), or may be granular in shape as illustratively depicted in FIG. 1(c).

In comparison to the mask body 10, the protrusions 20 may be referred to as micro protrusions due to their relatively smaller size.

The sputtering face of the mask body 10 refers to the face of the mask body 10 that is facing toward the target during a sputtering film forming process.

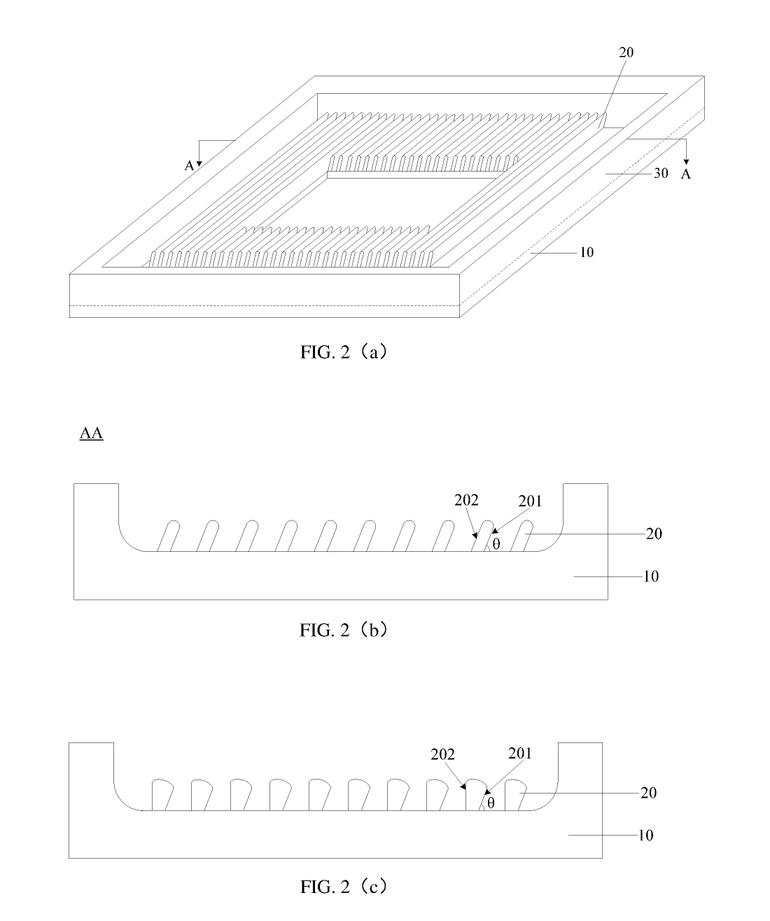

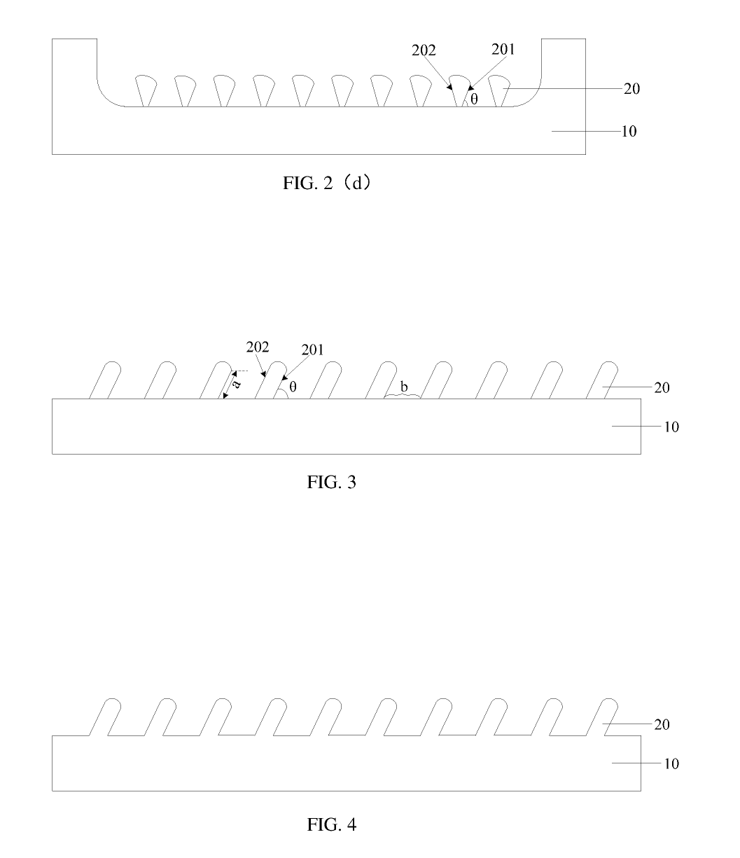

The mask body 10 is not limited to any particular structure, where the face of the mask body 10 upon which the protrusions 20 are positioned is flat as illustratively depicted in FIG. 1(a), FIG. 1(b), and FIG. 1(c), or where, as illustratively depicted in FIG. 2, the face of the mask body 10 upon which the protrusions 20 are positioned includes at the periphery a retaining wall 30, and the sputtering face of the mask body 10 does not include the retaining wall 30. The retaining wall 30 is to space apart the target and the sputtering face of the mask body 10 at a distance there-between. In addition, the retaining wall 30 and the part including the hollow portion may be formed integrally to form the mask body 10, as illustratively depicted in FIG. 2(a) where there shows no broken line.

The protrusions 20 may be formed integrally with the mask body 10, or may be formed onto the mask body 10 that has been pre-formed, and the present disclosure is not so limited.

The protrusions 20 and the mask body 10 may be the same or different in material, the material may be any suitable material in related technologies, such as aluminum material that has been surface treated.

The hollow portion of the mask body 10 is not limited to any particular size or shape which may be determined according to the size and shape of the film on the to-be-coated substrate.

The embodiments of the present disclosure provide a mask for sputtering film formation. The sputtering face of the mask body 10 includes a plurality of protrusions 20. When forming non-metal films via sputtering technologies, powders may fall into the space between the protrusions 20 of the mask body 10 and cannot readily move out therefrom during subsequent film forming processes, and therefore the powders are reduced during the film forming processes. Accordingly accumulation of the powders onto the substrate that is being coated is reduced, the quality of the film thus formed is secured, and the lifespan of the mask is improved. In comparison to related technologies, because the method according to the embodiments of the present disclosure does not require frequent cavity opening to clear out the powders, unwanted impact to manufacturing efficiencies is avoided, also avoided is unwanted impact of the cavity opening onto the film formation.

Optionally, and as shown in FIG. 1(a), FIG. 1(b), and FIG. 2(a), the mask body includes an outer periphery being a rectangle in shape, the protrusions 20 are strip-like protrusions positioned side-by-side along a longitudinal direction of a side of the mask body 10, and a longitudinal direction of the protrusions intersects the longitudinal direction of the side of the mask body.

The strip-like protrusions extend in a longitudinal direction intersecting the longitudinal direction of the side of the mask body, such that the longitudinal direction of the strip-like protrusions is not parallel to the longitudinal direction of the side of the mask body. The longitudinal direction of the strip-like protrusions may be perpendicular, or oblique, relative to the longitudinal direction of the side of the mask body.

When in use, a face of the mask is parallel to the ground floor, and when the mask body 10 includes an external periphery in the shape of a rectangle, the mask body 10 then includes a side that is perpendicular to the ground floor. When the protrusions are positioned side-by-side along a longitudinal direction of the side of the mask body 10, and when a longitudinal direction of the strip-like protrusions is perpendicular to the longitudinal direction of the side, the longitudinal direction of the strip-like protrusions is parallel to the ground surface, and therefore the powders do not slide down because of gravity after the powders accumulate onto the strip-like protrusions. Accordingly, and optionally, the longitudinal direction of the strip-like protrusions is perpendicular to the longitudinal direction of the side.

Accordingly, the strip-like protrusions may be straight strip-like protrusions as illustratively depicted in FIG. 1(a), FIG. 1(b) and FIG. 2(a), or curved strip-like protrusions.

Moreover, the two side walls of the strip-like protrusions that extend along the longitudinal direction may be positioned perpendicular to the mask body 10 as illustratively depicted in FIG. 1(a), or may be positioned obliquely relative to the mask body 10 as illustratively depicted in FIG. 1(b) and FIG. 2(a).

According to the embodiments of the present disclosure, and in comparison to particle-shaped protrusions, the protrusions 20 in the strip-like form are relatively better equipped to receive and trap the powders, and the received powders are less likely to move out of the strip-like protrusions.

Optionally, and as shown in FIG. 1(b) and FIG. 2, the strip-like protrusions are straight strip-like protrusions which include two side walls extending along a longitudinal direction, and the two side walls includes a first side wall 201 that is at an acute angle relative to the mask body 10.

Moreover, each first side wall 201 of the protrusions is positioned at an acute angle relative to the mask body 10, and the acute angle θ is not limited in the present disclosure and may be any acute angle between zero and 90 degrees. The first side wall 201 may be either one of the two side walls of the straight strip-like protrusion that extend along the longitudinal direction, which is the side wall positioned on the right side as depicted in the example shown in FIG. 2(b).

Accordingly, the first side walls 201 of the straight strip-like protrusions are at the same or a different angle relative to the mask body 10.

The straight strip-like protrusions may each include two side walls extending along a longitudinal direction, while another side wall such as the side wall 202 is not limited in its angle relative to the mask body 10. The angle of the side wall 202 relative to the mask body 10 may be an obtuse angle as illustratively depicted in FIG. 2(b), a right angle as illustratively depicted in FIG. 2(c), or an acute angle as illustratively depicted in FIG. 2(d).

In the embodiments of the present disclosure, and in comparison to curved strip-like protrusions, the straight strip-like protrusions are provided via relatively more simplified forming process. During sputtering film forming processes, the first side wall 201 faces upward when the mask body is positioned vertically. When the first side wall 201 is positioned at an acute angle relative to the mask body 10, the powders readily fall into the space to be captured between the protrusions 20, and the captured powders do not easily move out of the space merely due to gravity.

Optionally further, and as shown in FIG. 1(b) and FIG. 2, first side walls 201 of the straight strip-like protrusions are of the same slope.

Here, the straight strip-like protrusions are of the same angle relative to the first side wall 201; and in other words, the first side walls 201 of the straight strip-like protrusions are of the same angle relative to the mask body 10.

The inclination angle of each of the first side walls 201 of the straight strip-like protrusions is not limited to any value, as long as the inclination angle is at an acute angle. When the angle between the first side wall 201 and the mask body 10 is between 45 to 60 degrees, at which the amount of the powders that can be captured between the protrusions 20 is at its most, and the captured powders do not easily move out from where they are captured between the protrusions 20. Optionally further, the first side wall 201 is at an angle of 45 to 60 degrees relative to the mask body 10. Optionally yet further, the first side wall 201 is at an angle of 60 degrees relative to the mask body 10.

In the embodiments of the present disclosure, because the first side walls 201 of the straight strip-like protrusions are of the same slope, such that the powders may fall uniformly into the space between the protrusions 20 of the mask body 10. Accordingly the unwanted opposite may be avoided where, when the first side walls 201 of the straight strip-like protrusions are of different slopes, powders fall to the protrusions in variable amounts, and the uniformity of the film as formed is thus negatively affected.

Optionally, and as shown in FIG. 1(a), FIG. 1(b), FIG. 2(a), and FIG. 2(b), the straight strip-like protrusions each further include a second side wall 202 extending along the longitudinal direction of the protrusion, and the first side wall 201 and the second side wall 202 are parallel to each other.

In the embodiments of the present disclosure, the first side wall 201 and the second side wall 202 are parallel to each other, so as to simplify the process of manufacturing the protrusions 20.

When the first side walls 201 of the straight strip-like protrusions are at the same angle relative to the mask body 10, and when the first side wall 201 is parallel to the second side wall 202, a distance between the first side wall 201 of a straight strip-like protrusion and the second side wall 202 of an adjacent straight strip-like protrusion remains the same from a point closer to the mask body 10 to a point farther away from the mask body 10. When the first side wall 201 is not parallel to the second side wall 202, a distance between the first side wall 201 of a straight strip-like protrusion and the second side wall 202 of an adjacent straight strip-like protrusion gradually increases or decreases from a point closer to the mask body 10 to a point farther away from the mask body 10. When the distance between the first side wall 201 of a straight strip-like protrusion and the second side wall 202 of an adjacent straight strip-like protrusion gradually increases from a point closer to the mask body 10 to a point farther away from the mask body 10, the powders may, after being received between the protrusions 20, readily move out therefrom. When the distance between the first side wall 201 of a straight strip-like protrusion and the second side wall 202 of an adjacent straight strip-like protrusion gradually decreases from a point closer to the mask body 10 to a point farther away from the mask body 10, the powders may not readily fall into and be received between the protrusions 20. Accordingly, when the first side wall 201 is parallel to the second side wall 202, the powders may readily be received between the protrusions, and also may not readily fall out therefrom.

Optionally, and as shown in FIG. 3, the first side wall 201 is of a width “a” that is 4 to 5 millimeters.

The first side wall 201 is of a two-dimensional planar shape including a width and a length, where the length extends along a longitudinal direction of the protrusions 20, and the width extends from a point closer to the mask body 10 to a point farther away from the mask body 10, or the width extends from a point farther away from the mask body 10 to a point closer to the mask body 10.

In the embodiments of the present disclosure, and when the width “a” of the first side wall 201 is too small, the accumulation of powders onto the first side wall 201 is relatively small; and when the width “a” of the first side wall 201 is too big, performances of the mask may be affected, and therefore optionally, the width “a” of the first side wall 201 is 4 to 5 millimeters.

Optionally, distance “b” between bottom portions of two adjacent protrusions 20 is 1 to 4 millimeters, where the bottom portions are each an end portion that contacts the mask body 10.

According to the embodiments of the present disclosure, if the distance “b” between bottom portions of two adjacent protrusions 20 is too small, while the powders are of certain size dimensions, the powders may not readily fall into the space between the protrusions 20. If the distance “b” between bottom portions of two adjacent protrusions 20 is too big, the powders may move out of the space between the protrusions 20 after having entered into the space. Accordingly, and optionally, the distance “b” between the bottom portions of the protrusions is 1 to 4 millimeters.

Optionally, and as shown in FIG. 1 through FIG. 4, the protrusions 20 include a top portion that is curved in shape and protrudes away from the mask body 10.

The protrusions 20 include a bottom portion that is an end portion contacting the mask body 10, and the protrusions include a top portion that is an end portion positioned farthest away from the mask body 10.

Optionally, the top portion of the protrusions 20 is part of a ball surface.

In the embodiments of the present disclosure, the top portion of the protrusion 20 is curved so as to avoid unwanted electrical discharge from the top portion, in comparison to protrusions with a flat or pointy top portion.

Optionally, and as shown in FIG. 1 through FIG. 4, the protrusions 20 are uniformly positioned on the mask body 10.

The mask body 10 includes a hollow portion and a non-hollow portion, where the protrusions 20 are uniformly positioned in the non-hollow portion.

In the embodiments of the present disclosure, the protrusions 20 are uniformly positioned on the mask body 10, so as to enable a uniform distribution of the powders between the protrusions 20, and hence to secure the quality uniformity of the film as formed.

Optionally, and as shown in FIG. 4, the protrusions 20 and the mask body 10 are integrally formed.

In the embodiments of the present disclosure, the design where the protrusions 20 and the mask body 10 are integrally formed simplifies the film forming process.

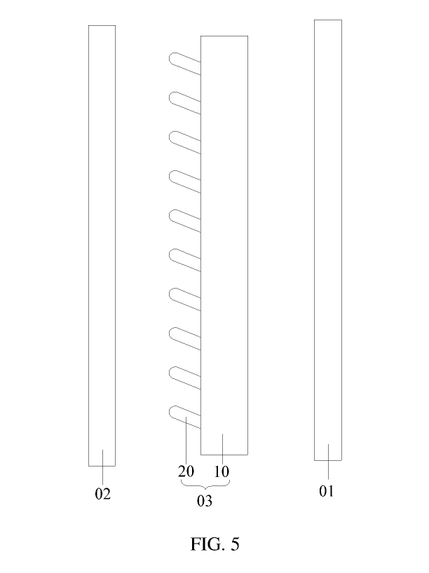

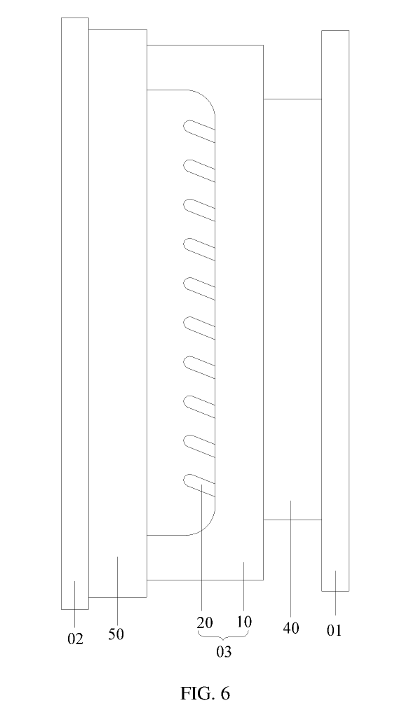

As shown in FIG. 5 and FIG. 6, the embodiments of the present disclosure provide a sputtering device including: a substrate platform 01, a target holder 02 to hold a target, and a mask 03 positioned between the substrate platform 01 and the target holder 02. The mask 03 is the mask described herein above, and the protrusions 20 of the mask 03 are directed toward the target holder 02.

As shown in FIG. 5 and FIG. 6, the substrate platform 01 is used to position the to-be-coated substrate 40, and the target holder 02 is to hold the target 50.

It should be noted that, and as illustratively depicted in FIG. 6, a retaining wall 30 is formed at the periphery of the mask body 10 so as to form a closed space among the to-be-coated substrate 40, the mask 03 and the target 50, to keep a certain distance between the target 50 and the mask 03, to avoid sputtering target atoms onto the cavity wall during sputtering film formation, and thus to avoid inconvenience associated with subsequence equipment maintenance. Accordingly, the mask 03 is adjusted in width and length based on practical requirements so as to effectuate smooth sputtering of target atoms onto the to-be-coated substrate 40 and to also avoid sputtering target atoms onto the cavity wall.

In the embodiments of the present disclosure, and during the sputtering film formation, the target atoms in one portion accumulate onto the to-be-coated substrate 40, and the target atoms in another portion accumulate onto the mask 03. With the existence of the protrusions 20 positioned on the sputtering face of the mask body 10, the protrusions 20 being directed toward the target, and once the powders are received between the protrusions 20 of the mask body 10, the powders do not readily move out therefrom in subsequent film forming processes, such that falling of the powders onto the to-be-coated substrate is avoided during film forming, the film quality is secured, and also the lifespan of the mask is extended. In comparison to related technologies, because the method according to the embodiments of the present disclosure does not require frequent cavity opening to clear out the powders, unwanted impact to manufacturing efficiencies is avoided, also avoided is unwanted impact of the cavity opening onto the film formation.

What is described herein above relates in detail to the embodiments of the present disclosure, however, the scope of the present invention is not thus limited, and technical personnel skilled in the art may readily obtain alterations and alternatives without departing from the present disclosure, where the alterations and alternatives are within the scope of the present disclosure. Accordingly, the scope of the present invention is defined by the scope of the claims.

What is claimed is:

1. A mask for sputtering film formation, the mask comprising a mask body, wherein the mask body comprises a sputtering face with a plurality of protrusions positioned thereupon.

2. The mask of claim 1, wherein the mask body comprises an outer periphery having a rectangle shape, the protrusions are strip-like protrusions positioned side-by-side along a longitudinal direction of a side of the mask body, and a longitudinal direction of the protrusions intersects the longitudinal direction of the side of the mask body.

3. The mask of claim 2, wherein the strip-like protrusions are straight strip-like protrusions each comprising two side walls extending along the longitudinal direction of the strip-like protrusions, and the two side walls comprise a first side wall at an acute angle relative to the mask body.

4. The mask of claim 3, wherein the first side walls of the straight strip-like protrusions are at an identical acute angle relative to the mask body.

5. The mask of claim 4, wherein the acute angle of the first side wall relative to the mask body is in a range of 45 degrees to 60 degrees.

6. The mask of claim 3, wherein the two side walls further comprise a second side wall arranged obliquely relative to the mask body.

7. The mask of claim 6, wherein the first and second side walls are parallel to each other.

8. The mask of claim 3, wherein the first side wall is of a width between 4 and 5 millimeters.

9. The mask of claim 1, wherein two adjacent protrusions comprise bottom portions spaced apart from each other by a distance between 1 millimeter and 4 millimeters, and the bottom portions are end portions contacting the mask body.

10. The mask of claim 1, wherein each of the protrusions has a curved top protruding away from the mask body.

11. The mask of claim 1, wherein the protrusions are uniformly positioned on the mask body.

12. The mask of claim 1, wherein the protrusions are integrally formed with the mask body.

13. The mask of claim 1, wherein the protrusions are granular in shape.

14. The mask of claim 1, further comprising a retaining wall positioned at a periphery of a face of the mask body upon which the protrusions are positioned.

15. A sputtering device, comprising:
a substrate platform,
a target holder to position a target, and
a mask positioned between the substrate platform and the target holder,
wherein the mask comprises a mask body, the mask body comprising a sputtering face with a plurality of protrusions positioned thereupon.
